(19) United States
(12) Patent Application Publication
(10) Pub. No.: US 2016/0343746 A1
(43) Pub. Date: Nov. 24, 2016

(54) DOPING METHOD AND DOPING APPARATUS OF ARRAY SUBSTRATE

(71) Applicant: SHENZHEN CHINA STAR OPTOELECTRONICS TECHNOLOGY CO., LTD., Shenzhen City, Guangdong (CN)

(72) Inventors: Jingfeng XUE, Shenzhen, Guangdong (CN); Gui CHEN, Shenzhen, Guangdong (CN); Sikun HAO, Shenzhen, Guangdong (CN); Xin ZHANG, Shenzhen, Guangdong (CN)

(73) Assignee: Shenzhen China Star Optoelectronics Technology Co., Ltd., Shenzhen, Guangdong (CN)

(21) Appl. No.: 14/426,251

(22) PCT Filed: Dec. 30, 2014
(86) PCT No.: PCT/CN2014/095559

§ 371 Date: Mar. 5, 2015

(30) Foreign Application Priority Data
Dec. 12, 2014 (CN) 201410770410.4

(51) Int. Cl. H01L 27/12; H01L 21/266; G03F 1/32; H01L 21/223; G03F 7/20; G03F 7/32; H01L 29/66; H01L 21/265

(52) U.S. Cl. CPC H01L 27/1288; H01L 27/127; H01L 29/6675; H01L 21/266; H01L 21/2652; H01L 21/223; H01L 29/66492; G03F 7/20; G03F 7/32; G03F 1/32

(57) ABSTRACT

A doping method and a doping apparatus of an array substrate are provided. The doping method includes: providing a substrate defined with to-be-heavily-doped region, to-be-lightly-doped region and to-be-doped channel region; forming a photoresist layer by a lithography process, the photoresist layer including first through third photoresist portions respectively corresponding to the to-be-heavily-doped region, the to-be-lightly-doped region and the to-be-doped channel region, the first photoresist portion being thinner than the second photoresist portion, the second photoresist portion being thinner than the third photoresist portion; and performing one time of doping on the to-be-heavily-doped region, the to-be-lightly-doped region and the to-be-doped region through the photoresist layer and thereby forming a heavily-doped region, a lightly-doped region and a channel region respectively. Therefore, the channel region, the heavily-doped region and the lightly-doped region can be obtained by one time of doping, simplified process and reduced cost are achieved.

### TECHNICAL FIELD

The invention relates to the field of substrate manufacturing technology, and particularly to a doping method and a doping apparatus of an array substrate.

### DESCRIPTION OF RELATED ART

A thin film transistor (TFT) is a basic circuit component in a liquid crystal display device for controlling luminance of a pixel and generally is made of an amorphous silicon structure. With the progress of technology, a low-temperature poly-silicon structure is increasingly used, and such structure can greatly improve the electrical performance of the thin film transistor.

For a thin film transistor formed using the low-temperature poly-silicon (LTPS) technology, the general standard LTPS thin film transistor has N-type heavily-doped regions on a poly-silicon layer respectively as a source and a drain, due to the two N-type heavily-doped regions having a relatively high doping concentration and a relatively small distance spaced from a gate conductor, an electric field near the drain is excessively strong and thereby a hot carrier effect is generated, so that the poly-silicon thin film transistor at off-state has the problem of leakage current and the component stability is severely affected. In order to solve the problem, the prior art performs three times of doping to channel region, heavily-doped region and lightly-doped region, so as to relieve the problem of leakage current.

Referring to FIG. 1A, FIG. 1B and FIG. 1C, FIG. 1A is a schematic view of a process of performing a first time of doping to a channel region, a heavily-doped region and a lightly-doped region in the prior art, FIG. 1B is a schematic view of a process of performing a second time of doping to the channel region, the heavily-doped region and the lightly-doped region in the prior art, and FIG. 1C is a schematic view of a process of performing a third time of doping to the channel region, the heavily-doped region and the lightly-doped region in the prior art. In particular, a poly-silicon 102 is formed on a substrate 101, and the poly-silicon 102 is defined with a to-be-heavily-doped region 103 (a doping concentration as required is a), a to-be-lightly-doped region 104 (a doping concentration as required is b) and a to-be-doped channel region 105 (a doping concentration as required is c). In FIG. 1A, the to-be-heavily-doped region 103, the to-be-lightly-doped region 104 and the to-be-doped channel region 105 are simultaneously doped with a first doping concentration of c. In FIG. 1B, a gate 106 is formed on the poly-silicon 102 and covering the channel region 105, a photoresist 108 then is formed by a photomask 107 and covering the to-be-lightly-doped region 104 and the gate 106, the photoresist 108 overlying the to-be-lightly-doped region 104 as well as the channel region 105 and the gate 106 as a whole have an uniform thickness; after that a second time of doping is performed to the to-be-heavily-doped region 103, and a doping concentration of the second time of doping is (a-b-c). In FIG. 1C, the photoresist 108 is removed, a third time of doping is performed to the to-be-heavily-doped region 103 and the to-be-lightly-doped region 104, and a doping concentration of the third time of doping is b.

It can be found from the above description, the doping process in the prior art is complex and three times of doping are needed, it not only increases the cost and production cycle, but also easily give rise to process error.

### SUMMARY

Accordingly, the invention provides a doping method and a doping apparatus of an array substrate, so as to realize one time of doping to form a channel region, a heavily-doped region and a lightly-doped region of a substrate at once and thereby simplify the process and reduce the cost.

In order to solve the above problem, a doping method of an array substrate provided by the invention includes: providing a substrate, wherein the substrate includes a substrate main body and a poly-silicon layer disposed on the substrate main body, the poly-silicon layer is defined with a to-be-heavily-doped region, a to-be-lightly-doped region and a to-be-doped channel region; forming a photoresist layer on the substrate by a lithography process, wherein the photoresist layer comprises a first photoresist portion corresponding to the to-be-heavily-doped region, a second photoresist portion corresponding to the to-be-lightly-doped region and a third photoresist portion corresponding to the to-be-doped channel region, the first photoresist portion is thinner than the second photoresist portion, and the second photoresist portion is thinner than the third photoresist portion; and using the photoresist layer to perform one time of doping to the to-be-heavily-doped region, the to-be-lightly-doped region and the to-be-doped channel region and thereby forming a heavily-doped region, a lightly-doped region and a channel region respectively corresponding to the to-be-heavily-doped region, the to-be-lightly-doped region and the to-be-doped channel region. The step of forming a photoresist layer on the substrate by a lithography process includes: forming a photoresist on the to-be-heavily-doped region, the to-be-lightly-doped region and the to-be-doped channel region in a uniform thickness; performing an exposure on the photoresist through a photomask, wherein the photomask comprises a first light-transmitting portion, a second light-transmitting portion and a third light-transmitting portion, light transmittances of the first light-transmitting portion, the second light-transmitting portion and the third light-transmitting portion are successively increased or decreased in that order; and developing the photoresist after the exposure by a developer to thereby form the first photoresist portion corresponding to the first light-transmitting portion, the second photoresist portion corresponding to the second light-transmitting portion and the third photoresist portion corresponding to the third light-transmitting portion.

In an embodiment, the photomask is a half-tone mask or a gray-level mask. The second light-transmitting portion of the half-tone mask corresponding to the second photoresist portion is a semi-transparent film, and a light transmittance of the semi-transparent film is between 0 to 100%. The second light-transmitting portion of the gray-level mask corresponding to the second photoresist portion has at least one slit to block a part of exposure light source and thereby achieve semi-transmissive effect, a light transmittance of the second light-transmitting portion of the gray-level mask is subjected to the control of the slit and between 0 to 100%.

In an embodiment, the step of using the photoresist layer to perform one time of doping to the to-be-heavily-doped region, the to-be-lightly-doped region and the to-be-doped channel region includes: using a diffusion method or an ion implantation process to perform the one time of doping to the to-be-heavily-doped region, the to-be-lightly-doped region and the to-be-doped channel region through the photoresist layer and thereby to form the heavily-doped region, the lightly-doped region and the channel region respectively corresponding to the to-be-heavily-doped region, the to-be-lightly-doped region and the to-be-doped channel region at once.

In order to solve the above problem, a doping method of an array substrate provided by the invention includes: providing a substrate, wherein the substrate is defined with a to-be-heavily-doped region, a to-be-lightly-doped region and a to-be-doped channel region; forming a photoresist layer on the substrate by a lithography process, wherein the photoresist layer comprises a first photoresist portion corresponding to the to-be-heavily-doped region, a second photoresist portion corresponding to the to-be-lightly-doped region and a third photoresist portion corresponding to the to-be-doped channel region, the first photoresist portion is thinner than the second photoresist portion, the second photoresist portion is thinner than the third photoresist portion; and performing one time of doping to the to-be-heavily-doped region, the to-be-lightly-doped region and the to-be-doped channel region through the photoresist layer and thereby forming a heavily-doped region, a lightly-doped region and a channel region respectively corresponding to the to-be-heavily-doped region, the to-be-lightly-doped region and the to-be-doped channel region.

In an embodiment, the substrate comprises a substrate main body and a poly-silicon layer disposed on the substrate main body, the poly-silicon layer is defined with the to-be-heavily-doped region, the to-be-lightly-doped region and the to-be-doped channel region.

In an embodiment, the step of forming a photoresist layer on the substrate by a lithography process includes: disposing a photoresist on the to-be-heavily-doped region, the to-be-lightly-doped region and the to-be-doped channel region in a uniform thickness; performing an exposure on the photoresist through a photomask, wherein the photomask comprises a first light-transmitting portion, a second light-transmitting portion and a third light-transmitting portion, light transmittances of the first light-transmitting portion, the second light-transmitting portion and the third light-transmitting portion are successively increased or decreased in that order; and developing the photoresist after the exposure by a developer to thereby form the first photoresist portion corresponding to the first light-transmitting portion, the second photoresist portion corresponding to the second light-transmitting portion and the third photoresist portion corresponding to the third light-transmitting portion.

In an embodiment, the photomask is a half-tone mask or a gray-level mask. The second light-transmitting portion of the half-tone mask corresponding to the second photoresist portion is a semi-transparent film, and a light transmittance of the semi-transparent film is between 0 to 100%. The second light-transmitting portion of the gray-level mask corresponding to the second photoresist portion has at least one slit to block a part of exposure light source and thereby achieve semi-transmissive effect, a light transmittance of the second light-transmitting portion of the gray-level mask is subjected to the control of the slit and between 0 to 100%.

In an embodiment, the step of performing one time of doping on the to-be-heavily-doped region, the to-be-lightly-doped region and the to-be-doped channel region through the photoresist layer includes: using a diffusion method or an ion implantation process to perform the one time of doping to the to-be-heavily-doped region, the to-be-lightly-doped region and the to-be-doped channel region through the photoresist layer and thereby to form the heavily-doped region, the lightly-doped region and the channel region respectively corresponding to the to-be-heavily-doped region, the to-be-lightly-doped region and the to-be-doped channel region at once.

In order to solve the above problem, a doping apparatus of an array substrate provided by the invention includes: a lithography device, configured for forming a photoresist layer on a substrate, wherein the substrate is defined with a to-be-heavily-doped region, a to-be-lightly-doped region and a to-be-doped channel region; the photoresist layer comprises a first photoresist portion corresponding to the to-be-heavily-doped region, a second photoresist portion corresponding to the to-be-lightly-doped region and a third photoresist portion corresponding to the to-be-doped channel region, the first photoresist portion is thinner than the second photoresist portion, the second photoresist portion is thinner than the third photoresist portion; and a doping device, configured for performing one time of doping to the to-be-heavily-doped region, the to-be-lightly-doped region and the to-be-doped channel region through the photoresist layer and thereby forming a heavily-doped region, a lightly-doped region and a channel region respectively corresponding to the to-be-heavily-doped region, the to-be-lightly-doped region and the to-be-doped region at once.

In an embodiment, the substrate includes a substrate main body and a poly-silicon layer disposed on the substrate main body, the poly-silicon layer is defined with the to-be-heavily-doped region, the to-be-lightly-doped region and the to-be-doped channel region.

In an embodiment, the lithography device includes a photoresist, a photomask, a developer and an exposure light source. The photoresist is configured for being disposed on the to-be-heavily-doped region, the to-be-lightly-doped region and the to-be-doped channel region in a uniform thickness. The photomask includes a first light-transmitting portion, a second light-transmitting portion and a third light-transmitting portion, light transmittances of the first light-transmitting portion, the second light-transmitting portion and the third light-transmitting portion are successively increased or decreased in that order. The exposure light source is configured for performing an exposure on the photoresist through the photomask. The developer is configured for developing the photoresist after the exposure to thereby form the first photoresist portion corresponding to the first light-transmitting portion, the second photoresist portion corresponding to the second light-transmitting portion and the third photoresist portion corresponding to the third light-transmitting portion.

In an embodiment, the photomask is a half-tone mask or a gray-level mask. The second light-transmitting portion of the half-tone mask corresponding to the second photoresist portion is a semi-transparent film, a light transmittance of the semi-transparent film is between 0 to 100%. The second light-transmitting portion of the gray-level mask corresponding to the second photoresist portion has at least one slit to block a part of the exposure light source and thereby achieve semi-transmissive effect, a light transmittance of the second light-transmitting portion of the gray-level mask is subjected to the control of the slit and between 0 to 100%.

In an embodiment, the doping device is configured for using a diffusion method or an ion implantation process to perform the one time of doping on the to-be-heavily-doped region, the to-be-lightly-doped region and the to-be-doped channel region through the photoresist layer and thereby to form the heavily-doped region, the lightly-doped region and the channel region respectively corresponding to the to-be-heavily-doped region, the to-be-lightly-doped region and the to-be-doped channel region at once.

By means of the above technical solutions, efficacy can be achieved by the invention is that: different from the prior art, the invention forms the photoresist layer on the substrate by the lithography process, and the formed photoresist layer having photoresist portions with different thicknesses, and the invention further uses the photoresist layer to perform one time of doping to allow dopant to pass through the photoresist portions with different thicknesses and then arrive at the substrate. When performing the one time of doping, the doping power is the same but the thicknesses of the photoresist portions are different, so that the quantities of dopant finally arriving at the substrate respectively through the photoresist portions with the different thicknesses are different and therefore the one time of doping can form the heavily-doped region, the lightly-doped region and the channel region with different doping concentrations at once. As a result, the process is simplified and the cost is reduced.

### BRIEF DESCRIPTION OF THE DRAWINGS

In order to more clearly illustrate the technical solutions of various embodiments of the present invention, drawings will be used in the description of embodiments will be given a brief description below. Apparently, the drawings in the following description only are some embodiments of the invention, the ordinary skill in the art can obtain other drawings according to these illustrated drawings without creative effort. In the drawings:

FIG. 1A is a schematic view of a process of performing a first doping to a channel region, a heavily-doped region and a lightly-doped region in the prior art;

FIG. 1B is a schematic view of a process of performing a second doping to the channel region, the heavily-doped region and the lightly-doped region in the prior art;

FIG. 1C is a schematic view of a process of performing a third doping to the channel region, the heavily-doped region and the lightly-doped region in the prior art;

FIG. 2 is a flowchart of a first embodiment of a doping method of an array substrate of the invention;

FIG. 3 is a schematic view of a process corresponding to the first embodiment of the doping method as shown in FIG. 2;

FIG. 4 is a schematic view of a nanoimprint lithography process in the first embodiment of the doping method as shown in FIG. 2;

FIG. 5 is a flowchart of a second embodiment of the doping method of an array substrate of the invention;

FIG. 6 is a schematic view of a process corresponding to the second embodiment of the doping method as shown in FIG. 5;

FIG. 7 is a structural schematic view of a gray-level mask in the second embodiment of the doping method as shown in FIG. 5;

FIG. 8 is a partial structural schematic view of a thin film transistor manufactured by combining the doping method of an array substrate of the invention; and

FIG. 9 is a schematic view of the using manner of a first embodiment of a doping apparatus of an array substrate of the invention in a process flow.

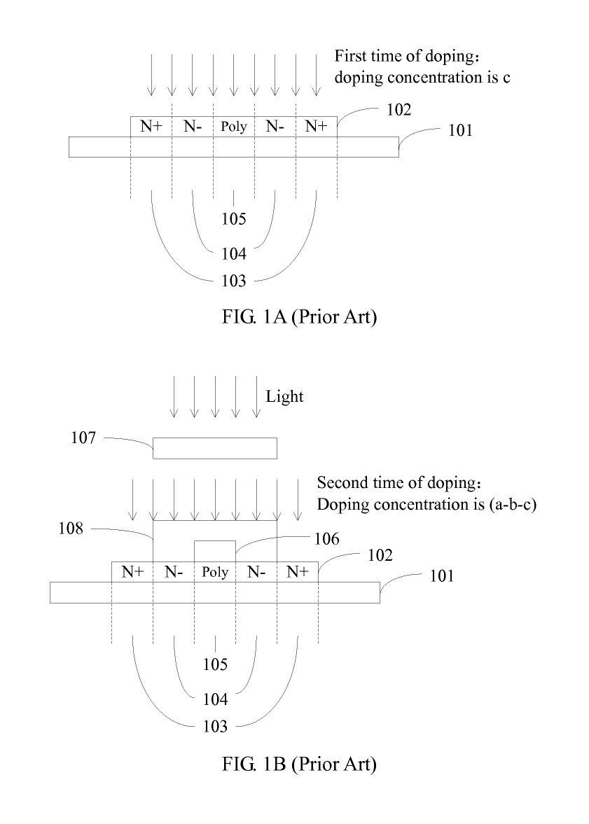

### DETAILED DESCRIPTION OF EMBODIMENTS

In the following, with reference to accompanying drawings of embodiments of the invention, technical solutions in the embodiments of the invention will be clearly and completely described. Apparently, the embodiments of the invention described below only are a part of embodiments of the invention, but not all embodiments. Based on the described embodiments of the invention, all other embodiments obtained by ordinary skill in the art without creative effort belong to the scope of protection of the invention.

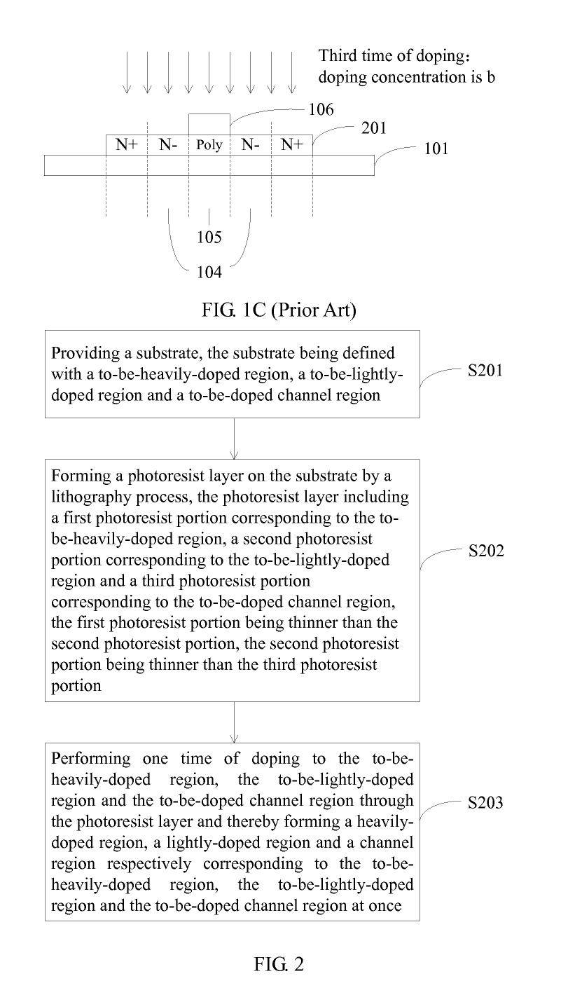

Referring to FIG. 2 and FIG. 3, FIG. 2 is a flowchart of a first embodiment of a doping method of an array substrate of the invention, and FIG. 3 is a schematic view of a process corresponding to the first embodiment of the doping method as shown in FIG. 2. Specifically, the doping method according to the first embodiment includes following steps:

S201: providing a substrate, the substrate being defined with a to-be-heavily-doped region, a to-be-lightly-doped region and a to-be-doped channel region.

Generally speaking, by performing processes such as hole machining, electroplating, etching and electronic component disposing to the substrate 301, functions such as electrical, magnetic or optical can be achieved. By doping a small amount of additional element or compound in the substrate 301, the substrate 301 can produce specific performance. Concretely speaking, for example, an N-type or P-type semiconductor material can be obtained by respectively doping phosphorus (P) or gallium (Ga) into a semiconductor silicon substrate, a fluorescent material which emits red light can be obtained by doping metal ion europium (Eu) into an inorganic solid compound yttrium oxide (Y₂O₃) substrate.

Since a concentration of dopant has a great impact on the performance of the substrate 301, the substrate 301 is doped with different concentrations of dopant would correspondingly have different performances, and the combination of different concentrations of dopant in the substrate 301 can achieve specific function. For example, for a lightly-doped drain (LDD) structure in a thin film transistor, the LDD structure includes an N-type heavily-doped region and an N-type lightly-doped region, carriers generated in the heavily-doped region diffuse toward the lightly-doped region, so that the problem of leakage current is relieved.

In this embodiment, the substrate 301 is defined with three to-be-doped regions requiring different doping concentrations, i.e., a to-be-heavily-doped region 302 requiring a doping concentration of h, a to-be-lightly-doped region 303 requiring a doping concentration of 1, and a to-be-doped channel region 304 requiring a doping concentration of c, where h>1>c. In other embodiment, a different number of regions requiring different doping concentrations can be set according to actual requirement, and the positional relationship among the regions also is not limited to that as shown in FIG. 3.

S202: forming a photoresist layer on the substrate by a lithography process, the photoresist layer including a first photoresist portion corresponding to the to-be-heavily-doped region, a second photoresist portion corresponding to the to-be-lightly-doped region and a third photoresist portion corresponding to the to-be-doped channel region, the first photoresist portion being thinner than the second photoresist portion, and the second photoresist portion being thinner than the third photoresist portion.

In this embodiment, before performing a doping on the substrate 301, a photoresist layer 305 is firstly formed on the substrate 301. The photoresist layer 305 is formed with a first photoresist portion 3051 corresponding to the to-be-heavily-doped region 302, a second photoresist portion 3052 corresponding to the to-be-lightly-doped region 303, and a third photoresist portion 3053 corresponding to the to-be-doped channel region 304. A thickness of the first photoresist portion 3051 is p₁, a thickness of the second photoresist portion 3052 is p₂, a thickness of the third photoresist portion 3053 is p₃, and p₁<p₂<p₃.

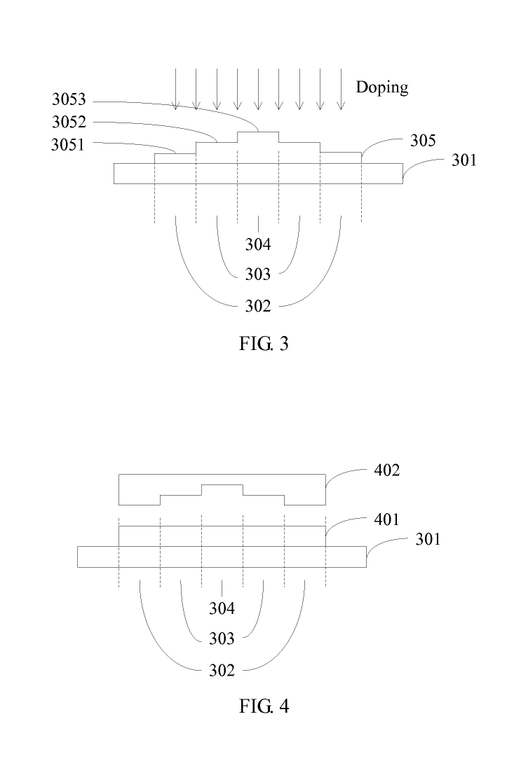

In this embodiment, a nanoimprint lithography process can be employed to form the photoresist layer 305. Referring to FIG. 4, FIG. 4 is a schematic view of a nanoimprint lithography process in the first embodiment of the doping method as shown in FIG. 2. Firstly, a layer of photoresist 401 is formed on the substrate 301 in a uniform thickness, a nanoimprint mold 402 then is downwardly pressed to make the photoresist 401 to flow and fill into a pattern of the nanoimprint mold 402, afterward the downward pressure applied to the nanoimprint mold 402 is increased to make the thicknesses of the photoresist 401 reach a required range, and finally the photoresist 401 is cured to form the photoresist layer. By designing the nanoimprint mold 402, the photoresist layer can form three photoresist portions respectively having the thicknesses p₁, p₂ and p₃.

Alternatively, in this embodiment, a traditional optical lithography process can be employed to form the photoresist layer 305. In particular, a layer of photoresist is formed on the substrate 301 in an uniform thickness, a strong/intense light passes a photomask and irradiates the photoresist, the portion of the photoresist being irradiated by the strong light would change its property, and then a corrosive liquid is used to clean the substrate 301 so as to remove the property-changed portion of the photoresist. By controlling the irradiated degree/level of the photoresist by the strong light, the quantity of photoresist with changed property can be controlled, and therefore by using three levels of light irradiation applied to the photoresists of three regions respectively, the photoresists with changed property in the three regions may have three different quantities, and after using a corrosive liquid to clean the irradiated photoresist, the photoresist layer 305 is finally formed on the substrate, and correspondingly the three regions respectively form three photoresist portions with different thicknesses p₁, p₂ and p₃.

S203: performing one time of doping to the to-be-heavily-doped region, the to-be-lightly-doped region and the to-be-doped channel region through the photoresist layer and thereby forming a heavily-doped region, a lightly-doped region and a channel region respectively corresponding to the to-be-heavily-doped region, the to-be-lightly-doped region and the to-be-doped channel region at once.

The photoresist layer 305 having three photoresist portions is formed after the step S202, and the photoresist layer 305 is overlying the substrate 301. After that, by performing one time of doping to the to-be-heavily-doped region 302, the to-be-lightly-doped region 303 and the to-be-doped channel region 304 through the photoresist layer 305, a heavily-doped region, a lightly-doped region and a channel region are formed on the substrate 301 at once.

Doping methods employed by substrates made of different materials generally are different, for example, a semiconductor silicon substrate generally uses a diffusion method or an ion implantation method, a light emitting material substrate mainly uses a chemical method such as high-temperature solid-phase method or sol-gel method. When a dopant passes through the photoresist layer 305 and implants into the substrate, due to the photoresist layer 305 has a certain hindering effect and photoresist portions with different thicknesses would have different hindering effects, and the doping process of the three regions in this embodiment is completed at once, so that, for the three regions, in the doping process, except the corresponding photoresist portions have different thicknesses, i.e., p₁<p₂<p₃, the other conditions are completely the same. Accordingly, the first photoresist portion with the thickness p₁ has the smallest hindering effect and corresponds to the to-be-heavily-doped region 302 requiring the doping concentration of h, the second photoresist portion with the thickness p₂ has the middle hindering effect and corresponds to the to-be-lightly-doped region 303 requiring the doping concentration of 1, the third photoresist portion with the thickness p₃ has the largest hindering effect and corresponds to the to-be-doped channel region 304 requiring the doping concentration of c.

Different from the prior art, this embodiment uses the lithography process to form a photoresist layer on the substrate and the photoresist layer having photoresist portions with different thicknesses, controls the thicknesses of the photoresist portions to achieve the restriction of doping hindering effects and thereby achieve the restriction of doping concentrations in different regions of the substrate, and therefore after the one time of doping, the substrate can be formed with a heavily-doped region, a lightly-doped region and a channel region with different doping concentrations at once, so that the doping process is simplified and the cost is reduced.

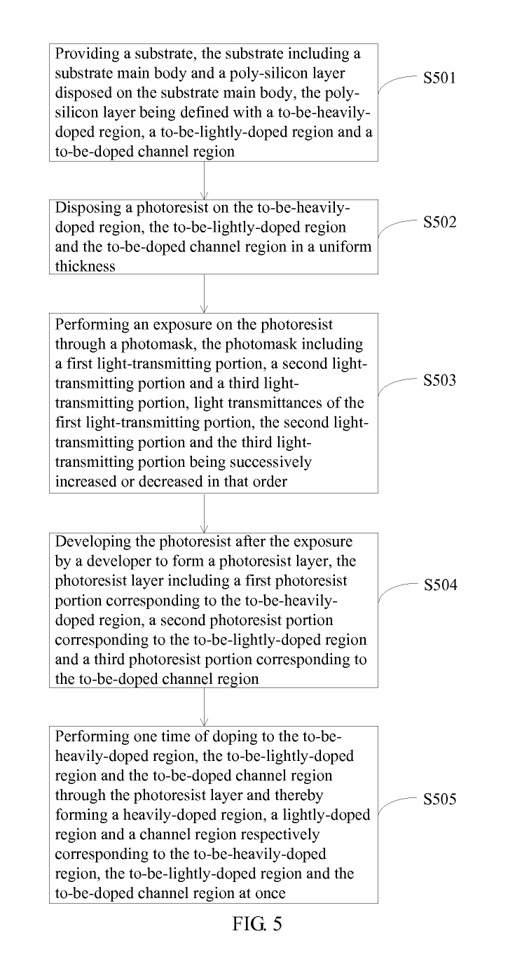

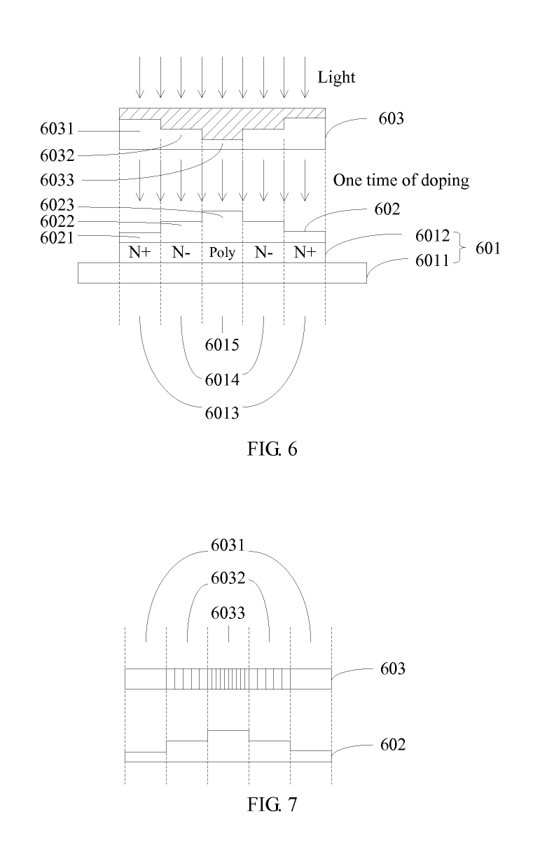

Referring to FIG. 5 and FIG. 6, FIG. 5 is a flowchart of a second embodiment of a doping method of an array substrate of the invention, and FIG. 6 is a schematic view of a process corresponding to the second embodiment of the doping method as shown in FIG. 5. Specifically, the doping method according to the second embodiment includes the following steps:

S501: providing a substrate, the substrate including a substrate main body and a poly-silicon layer disposed on the substrate main body, the poly-silicon layer being defined with a to-be-heavily-doped region, a to-be-lightly-doped region and a to-be-doped channel region.

In this embodiment, a substrate 601 includes a substrate main body 6011 and a poly-silicon layer 6012. The poly-silicon layer 6012 is defined with a to-be-heavily-doped region 6013, a to-be-lightly-doped region 6014 and a to-be-doped channel region 6015.

In order to achieve light and thin design and reduce the power consumption of LCD, a poly-silicon liquid crystal panel is increasingly used, and a poly-silicon structure thereof generally is obtained by processing an amorphous silicon structure. Specifically, in this embodiment, the formation of the poly-silicon layer 6012 employs a low temperature poly-silicon (LTPS) technology, a chemical vapor deposition process or a plasma-enhanced chemical vapor deposition process firstly is used to form an amorphous silicon layer on the substrate main body 6011, the substrate main body 6011 may be made of glass or quartz, an excimer laser then is used as a heat source, the laser produces a laser beam with uniform energy distribution after passing through a transmission system and strikes on the amorphous silicon layer, the amorphous silicon layer would be transformed into the poly-silicon layer 6012 after absorbing the energy of the excimer laser, the process generally is performed at 500-600 degrees Celsius, an ordinary glass substrate also can be withstood, and therefore the low temperature poly-silicon technology can realize applying the poly-silicon to the LCD display field at low cost.

In this embodiment, the substrate main body 6011 is a glass substrate, and the poly-silicon layer 6012 is a low temperature poly-silicon layer and used for manufacturing a low temperature poly-silicon thin film transistor. For an NMOS transistor, a source and a drain in the poly-silicon layer are N-type heavily-doped regions and correspondingly has a small distance spaced from a gate, a strong electric field would be generated near the drain and whereby a hot carrier effect occurs, the thin film transistor at off-state would have the problem of leakage current, and therefore a heavily-doped region, a lightly-doped region and a channel region are expected to be formed between the source and the drain so as to relieve the problem of leakage current. Correspondingly, in the step S501, it is needed to define the to-be-heavily-doped region 6013, the to-be-lightly-doped region 6014 and the to-be-doped channel region 6015 on the poly-silicon layer 6012.

S502: disposing a photoresist on the to-be-heavily-doped region, the to-be-lightly-doped region and the to-be-doped channel region in a uniform thickness.

The photoresist (not shown) includes a photosensitive resin, a sensitizer and a solvent. The photosensitive resin would take place a photo-curing reaction after light illumination and then physical properties especially solubility and affinity of the photoresist are changed. Photoresists generally are classified into two groups: positive photoresist and negative photoresist, the negative photoresist forms an insoluble substance after light illumination, and the positive photoresist forms a soluble substance after light illumination. In this embodiment, the photoresist is a positive photoresist.

The photoresist is coated on the substrate 601 by a spin coating method, and the spin coating method mainly has two ways: one is static coating, i.e., photoresist is dropped when the substrate 601 is static, the substrate 601 then is accelerated to rotate for photoresist spinning, and finally the solvent is evaporated; the other one is dynamic coating, i.e., photoresist is dropped when the substrate 601 is rotated at a low speed, the substrate 601 then is rotated at a high speed for photoresist spinning, and finally the solvent is evaporated. In order to obtain a uniform photoresist layer, this embodiment employs the dynamic coating and controls the time point of rotation acceleration to make the photoresist is spun at a relatively high speed as far as possible.

S503: performing an exposure on the photoresist through a photomask, the photomask including a first light-transmitting portion, a second light-transmitting portion and a third light-transmitting portion, light transmittances of the first light-transmitting portion, the second light-transmitting portion and the third light-transmitting portion being successively increased or decreased in that order.

The ultimate goal of this embodiment is to form a heavily-doped region, a lightly-doped region and a channel region with different doping concentrations on the poly-silicon 6012, the doping concentrations determine the thicknesses of the photoresist layer 602 and the power of one time of doping, and the thicknesses of the photoresist 602 determine the thickness of the photoresist and corresponding exposure rates; based on these, the exposure light source and the exposure speed in the exposure process, the light transmittances of the photomask 603 and the thickness of the photoresist in the coating process can be determined.

In this embodiment, the exposure light source employs an ultraviolet (UV) light source, the photoresist is a positive photoresist, and therefore the used photomask 603 has a first light-transmitting portion 6031 with a light transmittance of t₁, a second light-transmitting portion 6032 with a light transmittance of t₂ and a third light-transmitting portion 6033 with a light transmittance of t₃. The light transmittances of the first light-transmitting portion 6031, the second light-transmitting portion 6032 and the third light-transmitting portion 6033 are successively decreased, i.e., t₁>t₂>t₃. If the photoresist is a negative photoresist, the light transmittances of the first light-transmitting portion 6031, the second light-transmitting portion 6032 and the third light-transmitting portion 6033 are successively increased, i.e., t₁<t₂<t₃. The following description is related to the photomask corresponding to the positive photoresist, and relevant parameters of the photomask corresponding to the negative photoresist can be correspondingly adjusted.

The ultraviolet light passes through the photomask 603 to perform an exposure on the photoresist, the photomask 603 and the photoresist may have three types of positional relationships: the first one is that the photomask 603 is disposed on the photoresist and directly in contact with the photoresist, the exposure accuracy is high but the photomask would easily contaminate the photomask 603 and cause the loss of the photomask 603; the second one is that the photomask 603 is disposed slightly spaced from the photoresist with a certain distance, the lifespan of the photomask 603 can be ensured but the exposure accuracy is not high because of diffraction effect; the third one is that the photomask 603 and the photoresist have a lens disposed therebetween, the problems associated with the foregoing positional relationships are solved, but the disposition of the lens causes a high manufacturing cost. In this embodiment, the photomask 603 is disposed slightly spaced from the photoresist with a certain distance, i.e., the second positional relationship is employed.

Specifically, the photomask 603 in this embodiment may be a half-tone mask, the first light-transmitting portion thereof is a transparent portion, the second light-transmitting portion 6032 is a semi-transparent portion, and the third light-transmitting portion 6033 is an opaque portion, and a light transmittance of the second light-transmitting portion 6032 being a semi-transparent portion is between 0 to 100%. The photomask 603 may be a gray-level mask instead, the first light-transmitting portion 6031 is a full-transmissive portion, the second light-transmitting portion 6032 is a semi-transmissive portion, the third light-transmitting portion 6033 is a light non-transmissive portion, and the second light-transmitting portion 6032 has at least one slit to block a part of exposure light source and thereby achieve the semi-transmissive effect, the slit-controlled transmittance is between 0 to 100%. For details, please refer to FIG. 7, FIG. 7 is a structural schematic view of a gray-level mask in the second embodiment of the doping method as shown in FIG. 5, the amount/number of slit in the first light-transmitting portion 6031 is the least, and the amount of slit in the third light-transmitting portion 6033 is the most.

S504: developing the photoresist after the exposure by a developer (e.g., a developing solution) to form a photoresist layer, the photoresist layer including a first photoresist portion corresponding to the first light-transmitting portion, a second photoresist portion corresponding to the second light-transmitting portion and a third photoresist portion corresponding to the third light-transmitting portion.

After performing the exposure on the photoresist by using the light-transmitting portions with different light transmittances, the photoresists in regions corresponding to the different light-transmitting portions take place different curing reactions. After that, by using a developing solution to develop the photoresist, the photoresist layer 602 is finally formed. The photoresist corresponding to the first light-transmitting portion 6031 forms the first photoresist portion 6021 with a thickness of p₁, the photoresist corresponding to the second light-transmitting portion 6032 forms the second photoresist portion 6022 with a thickness of p₂, the photoresist corresponding to the third light-transmitting portion 6033 forms the third photoresist portion 6023 with a thickness of p₃, because the light transmittances satisfy that t₁>t₂>t₃, the thicknesses of the photoresist portions correspondingly satisfy that p₁<P₂<p₃.

Because this embodiment uses the positive photoresist, the developing solution correspondingly uses tetramethylammonium hydroxide (TMAOH), the photoresist produces a carboxylic acid during the exposure process, the alkali in the developing solution is neutralized with the acid to make the light-exposed photoresist be dissolved into the developing solution, and the unexposed photoresist is not affected. A concrete developing process may be an immersion-type developing or a continuously spraying type developing. The immersion-type developing is immersing the whole substrate 601 in the developing solution, and therefore such method consumes more developing solution and has poor developing uniformity. The continuously spraying type developing is using one or multiple (i.e., more than one) nozzles to spray the developing solution on the surface of the substrate 601 and meanwhile the substrate 601 is rotated at a low speed, the dissolution of the photoresist is realized and the developing uniformity is better. In this embodiment, the continuously spraying type developing is employed.

S505: performing one time of doping on the to-be-heavily-doped region, the to-be-lightly-doped region and the to-be-doped channel region through the photoresist layer and thereby forming a heavily-doped region, a lightly-doped region and a channel region respectively corresponding to the to-be-heavily-doped region, the to-be-lightly-doped region and the to-be-doped channel region at once.

The photoresist layer 602 is formed on the poly-silicon layer 6012, and the first photoresist portion 6021 with the thickness p₁ in the photoresist layer 602 corresponds to the to-be-heavily-doped region 6013, the second photoresist portion 6022 with the thickness p₂ corresponds to the to-be-lightly-doped region 6014, and the third photoresist portion 6023 with the thickness p₃ corresponds to the to-be-doped channel region 6015.

When the one time of doping starts, a nitrogen (N₂⁺ or N⁺) is doped into the poly-silicon layer 6012 after passing through the photoresist layer 602, and the doping method may be an ion implantation process or a diffusion method. The ion implantation process is ionizing the dopant and directly implanting the ionized dopant into the poly-silicon layer 6012 by magnetic field acceleration so as to achieve the purpose of doping. The diffusion method is making the dopant to diffuse from a high concentration region to a low concentration region under the drive of high temperature. In this embodiment, the ion implantation process is employed, and the magnitude of used energy for implantation is determined by the thicknesses of the photoresist layer 602 and the doping concentrations of the poly-silicon layer 6012. The ions pass through the photoresist layer 602 by a certain energy and then are implanted into the poly-silicon layer 6012, due to the hindering effects of the different thicknesses in the photoresist layer 602, the quantities of implanted ions in different regions of the poly-silicon layer 6012 are different, and correspondingly the heavily-doped region, the lightly-doped region and the channel region with different doping concentrations can be formed.

Different from the prior art, this embodiment firstly coats a layer of photoresist on the poly-silicon layer and uses a photomask to perform an exposure on the photoresist, the photoresist after exposure then is developed by a developer to form a photoresist layer with three different thicknesses. By controlling the thicknesses of the photoresist layer to achieve the restriction of doping hindering effects, the restriction of doping concentrations in the poly-silicon layer can be achieved, so that after the one time of doping, the heavily-doped region, the lightly-doped region and the channel region with different doping concentrations can be formed on the substrate at once, the doping process is simplified and the cost is reduced as a result.

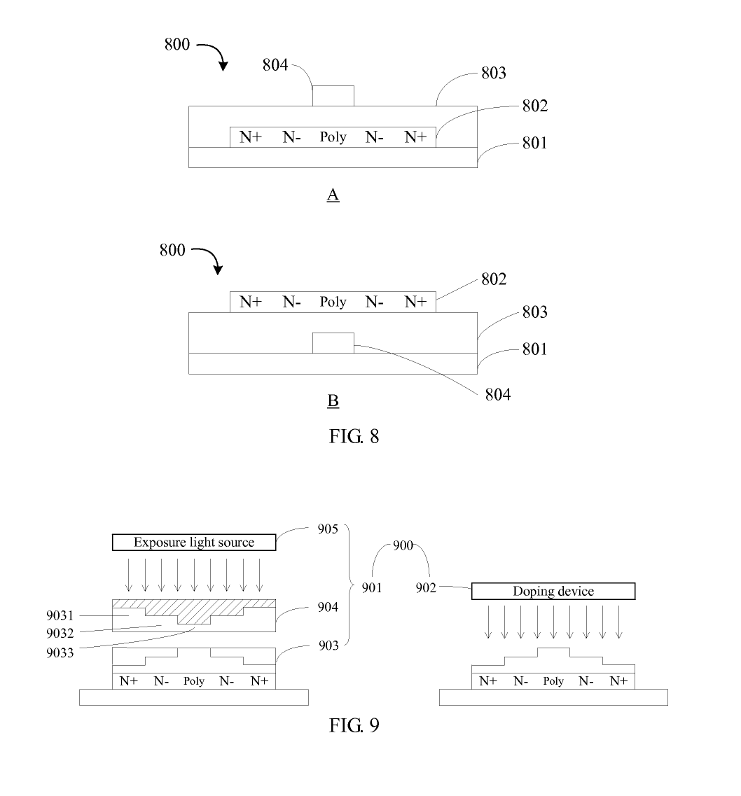

Referring to FIG. 8, FIG. 8 is a partial structural schematic view of a thin film transistor manufactured by combining the doping method of an array substrate of the invention.

The thin film transistor 800 includes a glass substrate 801, a poly-silicon layer 802, a gate insulating layer 803 and a gate electrode layer 804.

Please refer to the part A in FIG. 8, the poly-silicon layer 802 is disposed on the glass substrate 801 and includes a heavily-doped region 8021, a lightly-doped region 8022 and a channel region 8023, and the heavily-doped region 8021 is used as a source and a drain of the thin film transistor 800. The gate insulating layer 803 is disposed on the poly-silicon layer 802, and the gate electrode layer 804 is disposed on the gate insulating layer 803.

Another structure refers to the part B of FIG. 8, the gate electrode layer 804 is disposed on the glass substrate 801, the gate insulating layer 803 is disposed covering the gate electrode layer 804, and the poly-silicon layer 802 is disposed on the gate insulating layer 803.

Referring to FIG. 9, FIG. 9 is a schematic view of the using manner of a first embodiment of a doping apparatus of an array substrate of the invention in a process flow. In particular, the doping apparatus according to this embodiment includes a lithography device 901 and a doping device 902. The lithography device 901 includes a photoresist 903, a photomask 904, a developer (not shown) and an exposure light source 905.

The lithography device 901 is configured (i.e., structured and arranged) for forming a photoresist layer on a substrate. The substrate is defined with a to-be-heavily-doped region, a to-be-lightly-doped region and a to-be-doped channel region. The photoresist layer has a first photoresist portion corresponding to the to-be-heavily-doped region, a second photoresist portion corresponding to the to-be-lightly-doped region, and a third photoresist portion corresponding to the to-be-doped channel region, the first photoresist portion is thinner than the second photoresist portion, and the second photoresist portion is thinner than the third photoresist portion.

A concrete working process of the lithography device is as follows:

S901: disposing a photoresist on the to-be-heavily-doped region, the to-be-lightly-doped region and the to-be-doped channel region in a uniform thickness.

The step S901 is similar to the step S502 in the second embodiment of the doping method of an array substrate, and thus will not be repeated.

S902: the exposure light source 905 performing an exposure on the photoresist 903 through the photomask 904.

The photoresist 903 may be a positive photoresist, the photomask 904 includes a first light-transmitting portion 9041, a second light-transmitting portion 9042 and a third light-transmitting portion 9043, a light transmittance of the first light-transmitting portion 9041 is greater than a light transmittance of the second light-transmitting portion 9042, and the light transmittance of the second light-transmitting portion 9042 is greater than a light transmittance of the third light-transmitting portion 9043. The step S902 is similar to the step S503 in the second embodiment of the doping method of an array substrate, and thus will not be repeated.

S903: using the developer to develop the photoresist after exposure to thereby form a photoresist layer.

The photoresist layer includes a first photoresist portion corresponding to the first light-transmitting portion, a second photoresist portion corresponding to the second light-transmitting portion and a third photoresist portion corresponding to the third light-transmitting portion. The step S903 is similar to the step S504 in the second embodiment of the doping method of an array substrate, and thus will not be repeated.

The doping device 902 is configured for performing one time of doping on the to-be-heavily-doped region, the to-be-lightly-doped region and the to-be-doped channel region through the photoresist layer and thereby forming a heavily-doped region, a lightly-doped region and a channel region respectively corresponding to the to-be-heavily-doped region, the to-be-lightly-doped region and the to-be-doped region at once. The concrete working process of the doping device 902 is similar to the step S505 in the second embodiment of the doping method of an array substrate, and thus will not be repeated.

Different from the prior art, this embodiment uses the lithography device to coat the photoresist on the substrate and uses the photomask and developer (e.g., developing solution) to perform exposure and developing operations on the photoresist to thereby form the photoresist layer with three different thicknesses on the substrate. Afterwards, this embodiment further uses the doping device to perform one time of doping to the substrate through the photoresist layer, so that the heavily-doped region, the lightly-doped region and the channel region with different doping concentrations can be formed on the substrate at once, the complexity of the doping apparatus is simplified, the running time of the doping apparatus as well as the cost are reduced.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A doping method of an array substrate, the doping method comprising:
providing a substrate, wherein the substrate comprises a substrate main body and a poly-silicon layer disposed on the substrate main body, the poly-silicon layer is defined with a to-be-heavily-doped region, a to-be-lightly-doped region and a to-be-doped channel region;
forming a photoresist layer on the substrate by a lithography process, wherein the photoresist layer comprises a first photoresist portion corresponding to the to-be-heavily-doped region, a second photoresist portion corresponding to the to-be-lightly-doped region and a third photoresist portion corresponding to the to-be-doped channel region, the first photoresist portion is thinner than the second photoresist portion, and the second photoresist portion is thinner than the third photoresist portion;
using the photoresist layer to perform one time of doping to the to-be-heavily-doped region, the to-be-lightly-doped region and the to-be-doped channel region and thereby forming a heavily-doped region, a lightly-doped region and a channel region respectively corresponding to the to-be-heavily-doped region, the to-be-lightly-doped region and the to-be-doped channel region;
wherein the step of forming a photoresist layer on the substrate by a lithography process comprises:
forming a photoresist on the to-be-heavily-doped region, the to-be-lightly-doped region and the to-be-doped channel region in a uniform thickness;
performing an exposure on the photoresist through a photomask, wherein the photomask comprises a first light-transmitting portion, a second light-transmitting portion and a third light-transmitting portion, light transmittances of the first light-transmitting portion, the second light-transmitting portion and the third light-transmitting portion are successively increased or decreased in that order; and
developing the photoresist after the exposure by a developer to thereby form the first photoresist portion corresponding to the first light-transmitting portion, the second photoresist portion corresponding to the second light-transmitting portion and the third photoresist portion corresponding to the third light-transmitting portion.

2. The doping method as claimed in claim 1, wherein the photomask is a half-tone mask or a gray-level mask; the second light-transmitting portion of the half-tone mask corresponding to the second photoresist portion is a semi-transparent film, and a light transmittance of the semi-transparent film is between 0 to 100%; the second light-transmitting portion of the gray-level mask corresponding to the second photoresist portion has at least one slit to block a part of exposure light source and thereby achieve semi-transmissive effect, a light transmittance of the second light-transmitting portion of the gray-level mask is subjected to the control of the slit and between 0 to 100%.

3. The doping method as claimed in claim 1, wherein the step of using the photoresist layer to perform one time of doping to the to-be-heavily-doped region, the to-be-lightly-doped region and the to-be-doped channel region comprises:
using a diffusion method or an ion implantation process to perform the one time of doping to the to-be-heavily-doped region, the to-be-lightly-doped region and the to-be-doped channel region through the photoresist layer and thereby to form the heavily-doped region, the lightly-doped region and the channel region respectively corresponding to the to-be-heavily-doped region, the to-be-lightly-doped region and the to-be-doped channel region at once.

4. The doping method as claimed in claim 2, wherein the step of using the photoresist layer to perform one time of doping to the to-be-heavily-doped region, the to-be-lightly-doped region and the to-be-doped channel region comprises:
using a diffusion method or an ion implantation process to perform the one time of doping to the to-be-heavily-doped region, the to-be-lightly-doped region and the to-be-doped channel region through the photoresist layer and thereby to form the heavily-doped region, the lightly-doped region and the channel region respectively corresponding to the to-be-heavily-doped region, the to-be-lightly-doped region and the to-be-doped channel region at once.

5. A doping method of an array substrate, the doping method comprising:
providing a substrate, wherein the substrate is defined with a to-be-heavily-doped region, a to-be-lightly-doped region and a to-be-doped channel region;
forming a photoresist layer on the substrate by a lithography process, wherein the photoresist layer comprises a first photoresist portion corresponding to the to-be-heavily-doped region, a second photoresist portion corresponding to the to-be-lightly-doped region and a third photoresist portion corresponding to the to-be-doped channel region, the first photoresist portion is thinner than the second photoresist portion, the second photoresist portion is thinner than the third photoresist portion;
performing one time of doping to the to-be-heavily-doped region, the to-be-lightly-doped region and the to-be-doped channel region through the photoresist layer and thereby forming a heavily-doped region, a lightly-doped region and a channel region respectively corresponding to the to-be-heavily-doped region, the to-be-lightly-doped region and the to-be-doped channel region.

6. The doping method as claimed in claim 5, wherein the substrate comprises a substrate main body and a poly-silicon layer disposed on the substrate main body, the poly-silicon layer is defined with the to-be-heavily-doped region, the to-be-lightly-doped region and the to-be-doped channel region.

7. The doping method as claimed in claim 5, wherein the step of forming a photoresist layer on the substrate by a lithography process comprises:
disposing a photoresist on the to-be-heavily-doped region, the to-be-lightly-doped region and the to-be-doped channel region in a uniform thickness;
performing an exposure on the photoresist through a photomask, wherein the photomask comprises a first light-transmitting portion, a second light-transmitting portion and a third light-transmitting portion, light transmittances of the first light-transmitting portion, the second light-transmitting portion and the third light-transmitting portion are successively increased or decreased in that order;
developing the photoresist after the exposure by a developer to thereby form the first photoresist portion corresponding to the first light-transmitting portion, the second photoresist portion corresponding to the second light-transmitting portion and the third photoresist portion corresponding to the third light-transmitting portion.

8. The doping method as claimed in claim 7, wherein the photomask is a half-tone mask or a gray-level mask; the second light-transmitting portion of the half-tone mask corresponding to the second photoresist portion is a semi-transparent film, and a light transmittance of the semi-transparent film is between 0 to 100%; the second light-transmitting portion of the gray-level mask corresponding to the second photoresist portion has at least one slit to block a part of exposure light source and thereby achieve semi-transmissive effect, a light transmittance of the second light-transmitting portion of the gray-level mask is subjected to the control of the slit and between 0 to 100%.

9. The doping method as claimed in claim 5, wherein the step of performing one time of doping on the to-be-heavily-doped region, the to-be-lightly-doped region and the to-be-doped channel region through the photoresist layer comprises:
using a diffusion method or an ion implantation process to perform the one time of doping to the to-be-heavily-doped region, the to-be-lightly-doped region and the to-be-doped channel region through the photoresist layer and thereby to form the heavily-doped region, the lightly-doped region and the channel region respectively corresponding to the to-be-heavily-doped region, the to-be-lightly-doped region and the to-be-doped channel region at once.

10. The doping method as claimed in claim 6, wherein the step of performing one time of doping on the to-be-heavily-doped region, the to-be-lightly-doped region and the to-be-doped channel region through the photoresist layer comprises:
using a diffusion method or an ion implantation process to perform the one time of doping to the to-be-heavily-doped region, the to-be-lightly-doped region and the to-be-doped channel region through the photoresist layer and thereby to form the heavily-doped region, the lightly-doped region and the channel region respectively corresponding to the to-be-heavily-doped region, the to-be-lightly-doped region and the to-be-doped channel region at once.

11. The doping method as claimed in claim 7, wherein the step of performing one time of doping on the to-be-heavily-doped region, the to-be-lightly-doped region and the to-be-doped channel region through the photoresist layer comprises:
using a diffusion method or an ion implantation process to perform the one time of doping to the to-be-heavily-doped region, the to-be-lightly-doped region and the to-be-doped channel region through the photoresist layer and thereby to form the heavily-doped region, the lightly-doped region and the channel region respectively corresponding to the to-be-heavily-doped region, the to-be-lightly-doped region and the to-be-doped channel region at once.

12. The doping method as claimed in claim 8, wherein the step of performing one time of doping on the to-be-heavily-doped region, the to-be-lightly-doped region and the to-be-doped channel region through the photoresist layer comprises:
using a diffusion method or an ion implantation process to perform the one time of doping to the to-be-heavily-doped region, the to-be-lightly-doped region and the to-be-doped channel region through the photoresist layer and thereby to form the heavily-doped region, the lightly-doped region and the channel region respectively corresponding to the to-be-heavily-doped region, the to-be-lightly-doped region and the to-be-doped channel region at once.

13. A doping apparatus of an array substrate, the doping apparatus comprising:
a lithography device, configured for forming a photoresist layer on a substrate, wherein the substrate is defined with a to-be-heavily-doped region, a to-be-lightly-doped region and a to-be-doped channel region; the photoresist layer comprises a first photoresist portion corresponding to the to-be-heavily-doped region, a second photoresist portion corresponding to the to-be-lightly-doped region and a third photoresist portion corresponding to the to-be-doped channel region, the first photoresist portion is thinner than the second photoresist portion, the second photoresist portion is thinner than the third photoresist portion; and
a doping device, configured for performing one time of doping to the to-be-heavily-doped region, the to-be-lightly-doped region and the to-be-doped channel region through the photoresist layer and thereby forming a heavily-doped region, a lightly-doped region and a channel region respectively corresponding to the to-be-heavily-doped region, the to-be-lightly-doped region and the to-be-doped region at once.

14. The doping apparatus as claimed in claim 13, wherein the substrate comprises a substrate main body and a poly-silicon layer disposed on the substrate main body, the poly-silicon layer is defined with the to-be-heavily-doped region, the to-be-lightly-doped region and the to-be-doped channel region.

15. The doping apparatus as claimed in claim 13, wherein the lithography device comprises a photoresist, a photomask, a developer and an exposure light source;
the photoresist is configured for being disposed on the to-be-heavily-doped region, the to-be-lightly-doped region and the to-be-doped channel region in a uniform thickness;
the photomask comprises a first light-transmitting portion, a second light-transmitting portion and a third light-transmitting portion, light transmittances of the first light-transmitting portion, the second light-transmitting portion and the third light-transmitting portion are successively increased or decreased in that order;
the exposure light source is configured for performing an exposure on the photoresist through the photomask;
the developer is configured for developing the photoresist after the exposure to thereby form the first photoresist portion corresponding to the first light-transmitting portion, the second photoresist portion corresponding to the second light-transmitting portion and the third photoresist portion corresponding to the third light-transmitting portion.

16. The doping apparatus as claimed in claim 15, wherein the photomask is a half-tone mask or a gray-level mask; the second light-transmitting portion of the half-tone mask corresponding to the second photoresist portion is a semi-transparent film, a light transmittance of the semi-transparent film is between 0 to 100%; the second light-transmitting portion of the gray-level mask corresponding to the second photoresist portion has at least one slit to block a part of the exposure light source and thereby achieve semi-transmissive effect, a light transmittance of the second light-transmitting portion of the gray-level mask is subjected to the control of the slit and between 0 to 100%.

17. The doping apparatus as claimed in claim 13, wherein the doping device is configured for using a diffusion method or an ion implantation process to perform the one time of doping on the to-be-heavily-doped region, the to-be-lightly-doped region and the to-be-doped channel region through the photoresist layer and thereby to form the heavily-doped region, the lightly-doped region and the channel region respectively corresponding to the to-be-heavily-doped region, the to-be-lightly-doped region and the to-be-doped channel region at once.

18. The doping apparatus as claimed in claim 14, wherein the doping device is configured for using a diffusion method or an ion implantation process to perform the one time of doping on the to-be-heavily-doped region, the to-be-lightly-doped region and the to-be-doped channel region through the photoresist layer and thereby to form the heavily-doped region, the lightly-doped region and the channel region respectively corresponding to the to-be-heavily-doped region, the to-be-lightly-doped region and the to-be-doped channel region at once.

19. The doping apparatus as claimed in claim 15, wherein the doping device is configured for using a diffusion method or an ion implantation process to perform the one time of doping on the to-be-heavily-doped region, the to-be-lightly-doped region and the to-be-doped channel region through the photoresist layer and thereby to form the heavily-doped region, the lightly-doped region and the channel region respectively corresponding to the to-be-heavily-doped region, the to-be-lightly-doped region and the to-be-doped channel region at once.

20. The doping apparatus as claimed in claim 16, wherein the doping device is configured for using a diffusion method or an ion implantation process to perform the one time of doping on the to-be-heavily-doped region, the to-be-lightly-doped region and the to-be-doped channel region through the photoresist layer and thereby to form the heavily-doped region, the lightly-doped region and the channel region respectively corresponding to the to-be-heavily-doped region, the to-be-lightly-doped region and the to-be-doped channel region at once.
